(19) United States
(12) Patent Application Publication
(10) Pub. No.: US 2025/0209422 A1
(43) Pub. Date: Jun. 26, 2025

(54) Systems and Methods for Providing a Recommendation for a Product Design Within a Collaborative System

(71) Applicant: CoLab Software Inc., St. John's (CA)

(72) Inventors: Jeremy William ANDREWS, St. John's (CA); Adam Michael KEATING, St. John's (CA); Peter Jeffrey GOSSE, Conception Bay South (CA); Patrick LECKEY, Ottawa (CA)

(21) Appl. No.: 18/982,594

(22) Filed: Dec. 16, 2024

Related U.S. Application Data
(60) Provisional application No. 63/613,872, filed on Dec. 22, 2023.

(51) Int. Cl. G06Q 10/101

(52) U.S. Cl. CPC G06Q 10/101

(57) ABSTRACT

Disclosed herein are a method and system for providing a recommendation for a product design within a collaborative system. The method involves receiving at least one design document related to a product; evaluating the at least one design document to identify one or more design characteristics associated with at least one of the product and a design process related to the product; identifying one or more related prior design feedback associated with the one or more design characteristics from a historical design data storage; evaluating the one or more related prior design feedback and a related prior design decision resulting from the one or more related prior design feedback to determine a relevance level of the related prior design decision for the product design; and generating the recommendation for the product design based at least on the relevance level of the related prior design decision.

### CROSS-REFERENCE TO RELATED APPLICATION

This application claims the benefit of U.S. Provisional Patent Application No. 63/613,872 filed Dec. 22, 2023, and the entire contents of U.S. Provisional Patent Application No. 63/613,872 are hereby incorporated herein in its entirety.

### FIELD

The described embodiments relate to systems and methods for providing a recommendation for a product design, and specifically, providing the recommendation for the product design within a collaborative system.

### BACKGROUND

Online collaborations between different entities are now a common method of facilitating completion of projects. In addition to increasing the flexibility in which individuals can collaborate and the geographical locations where the entities are located, online collaboration systems can improve the collaboration process. For example, design projects conducted via online collaborations can improve data management and feedback tracking.

### SUMMARY

The various embodiments described herein generally relate to methods (and associated systems configured to implement the methods) for providing recommendations for product designs within a collaborative system.

In accordance with an example embodiment, there is provided a method for providing a recommendation for a product design within a collaborative system. The method includes receiving at least one design document related to a product; evaluating the at least one design document to identify one or more design characteristics associated with at least one of the product and a design process related to the product; identifying one or more related prior design feedback associated with the one or more design characteristics from a historical design data storage, the one or more related prior design feedback comprising one or more user feedback inputs received during a collaborative design process between one or more users in respect of a different product design; evaluating the one or more related prior design feedback and a related prior design decision resulting from the one or more related prior design feedback to determine a relevance level of the related prior design decision for the product design; and generating the recommendation for the product design based at least on the relevance level of the related prior design decision.

In some embodiments, evaluating the at least one design document to identify one or more design characteristics includes determining a geometry of a computer-generated model representing at least one portion of the product.

In some embodiments, evaluating the at least one design document to identify one or more design characteristics includes parsing a document metadata of the at least one design document.

In some embodiments, evaluating the at least one design document to identify one or more design characteristics includes identifying a product structure for the product, the product structure defining one or more hierarchical relationships between the product and one or more subcomponents of the product.

In some embodiments, evaluating the at least one design document to identify one or more design characteristics includes identifying a workspace associated with the product design within the collaborative system; analyzing a workspace metadata associated with the workspace; and determining one or more design trends from the workspace metadata.

In some embodiments, identifying the one or more related prior design feedback associated with the one or more design characteristics from the historical design data storage includes applying a product design data model to the one or more design characteristics to identify a plurality of related prior design feedback along with a confidence level for each related prior design feedback, the product design data model being trained on a plurality of prior design feedback received during a plurality of prior product designs for a plurality of products, and the product design data model being trained to correlate one or more prior design feedback with the one or more design characteristics; and selecting the one or more related prior design feedback from the plurality of related prior design feedback.

In some embodiments, selecting the one or more related prior design feedback from the plurality of related prior design feedback includes selecting the one or more related prior design feedback assigned a high priority level during the product design.

In some embodiments, selecting the one or more related prior design feedback from the plurality of related prior design feedback includes identifying the one or more related prior design feedback from the plurality of related prior design feedback that is generated during a feedback conversation that takes longer than a priority feedback time period.

In some embodiments, generating the recommendation for the product design includes evaluating the one or more related prior design feedback and the related prior design decision to determine one or more design risks associated with the product design; and offering the recommendation for the product design to address at least one design risk of the one or more design risks based on the related prior design decision.

In some embodiments, generating the recommendation for the product design includes generating a natural language summary for the one or more related prior design feedback and the related prior design decision.

In accordance with an example embodiment, there is provided a system for providing a recommendation for a product design within a collaborative system. The system includes a design data storage operable to store one or more prior design feedback comprising one or more user feedback inputs received during a collaborative design process between one or more users in respect of a different product design; and a processor configured to receive at least one design document related to a product; evaluate the at least one design document to identify one or more design characteristics associated with at least one of the product and a design process related to the product; identify, from the design data storage, one or more related prior design feedback associated with the one or more design characteristics; evaluate the one or more related prior design feedback and a related prior design decision resulting from the one or more related prior design feedback to determine a relevance level of the related prior design decision for the product design; and generate the recommendation for the product design based at least on the relevance level of the related prior design decision.

In some embodiments, the processor is configured to evaluate the at least one design document to identify one or more design characteristics by determining a geometry of a computer-generated model representing at least one portion of the product.

In some embodiments, the processor is configured to evaluate the at least one design document to identify one or more design characteristics by parsing a document metadata of the at least one design document.

In some embodiments, the processor is configured to evaluate the at least one design document to identify one or more design characteristics by identifying a product structure for the product, the product structure defining one or more hierarchical relationships between the product and one or more subcomponents of the product.

In some embodiments, the processor is configured to evaluate the at least one design document to identify one or more design characteristics by: identifying a workspace associated with the product design within the collaborative system; analyzing a workspace metadata associated with the workspace; and determining one or more design trends from the workspace metadata.

In some embodiments, the processor is configured to identify the one or more related prior design feedback associated with the one or more design characteristics by applying a product design data model to the one or more design characteristics to identify a plurality of related prior design feedback along with a confidence level for each related prior design feedback, the product design data model being trained on a plurality of prior design feedback received during a plurality of prior product designs for a plurality of products, and the product design data model being trained to correlate one or more prior design feedback with the one or more design characteristics; and select the one or more related prior design feedback from the plurality of related prior design feedback.

In some embodiments, the processor is configured to select the one or more related prior design feedback from the plurality of related prior design feedback by selecting the one or more related prior design feedback assigned a high priority level during the product design.

In some embodiments, the processor is configured to select the one or more related prior design feedback from the plurality of related prior design feedback by identifying the one or more related prior design feedback from the plurality of related prior design feedback that is generated during a feedback conversation that takes longer than a priority feedback time period.

In some embodiments, the processor is configured to generate the recommendation for the product design by evaluating the one or more related prior design feedback and the related prior design decision to determine one or more design risks associated with the product design; and offering the recommendation for the product design to address at least one design risk of the one or more design risks based on the related prior design decision.

In some embodiments, the processor is configured to generate the recommendation for the product design by generating a natural language summary for the one or more related prior design feedback and the related prior design decision.

In accordance with an example embodiment, there is provided a method for recommending one or more workflow requests for a product design within a collaborative system. The method includes receiving at least one design document related to a product; evaluating the at least one design document to identify one or more design characteristics associated with at least one of the product, a manufacturing process, and a design process related to the product; generating the one or more recommended workflow requests based on the one or more design characteristics; and receiving user data in response to the one or more recommended workflow requests.

In some embodiments, generating the one or more recommended workflow requests based on the one or more design characteristics includes determining from the one or more design characteristics one or more user configurable workflow requests.

In some embodiments, generating the one or more recommended workflow requests based on the one or more design characteristics includes identifying one or more related prior design feedback associated with the one or more design characteristics from a historical design data storage, the one or more related prior design feedback comprising one or more workflow data received in respect of a different product design; determining a relevance level for each workflow data of the one or more workflow data for the product design; and selecting the one or more recommended workflow requests based on the relevance level of the one or more workflow data.

In some embodiments, the method further includes receiving a user selection of one or more components within the at least one design document; and in response to receiving the user selection, generating the one or more recommended workflow requests based on the one or more design characteristics and the user selection.

In accordance with an example embodiment, there is provided a system for recommending one or more workflow requests for a product design within a collaborative system. The system includes a processor configured to: receive at least one design document related to a product; evaluate the at least one design document to identify one or more design characteristics associated with at least one of the product, a manufacturing process, and a design process related to the product; generate the one or more recommended workflow requests based on the one or more design characteristics; and receive user data in response to the one or more recommended workflow requests.

In some embodiments, the processor is configured to generate the one or more recommended workflow requests based on the one or more design characteristics by determining one or more user configurable workflow requests from the one or more design characteristics.

In some embodiments, the system further includes a design data storage operable to store one or more prior design feedback comprising one or more workflow data received in respect of a different product design, and the processor is configured to generate the one or more recommended workflow requests based on the one or more design characteristics by: identifying one or more related prior design feedback associated with the one or more design characteristics from the design data storage; determining a relevance level for each workflow data of the one or more workflow data for the product design; and selecting the one or more recommended workflow requests based on the relevance level of the one or more workflow data.

In some embodiments, the processor is further configured to receive a user selection of one or more components within the at least one design document; and in response to receiving the user selection, generate the one or more recommended workflow requests based on the one or more design characteristics and the user selection.

### BRIEF DESCRIPTION OF THE DRAWINGS

Several embodiments will now be described in detail with reference to the drawings, in which:

FIG. 1 is a block diagram of components interacting with a collaborative system in accordance with an example embodiment;

FIG. 2 is a block diagram of components of the collaborative system of FIG. 1;

FIG. 3 is a flowchart of an example method for providing a recommendation for a product design within the collaborative system of FIG. 1;

FIG. 4A is a graphical representation of an example product structure for an electric vehicle powertrain;

FIG. 4B is a graphical representation of another example product structure for an electric vehicle powertrain;

FIG. 5 is a graphical representation of example product structures for two electric vehicle powertrains;

FIG. 6A is an example user interface for a workspace of the collaborative system of FIG. 1;

FIG. 6B is another example user interface for a workspace of the collaborative system of FIG. 1;

FIG. 6C is another example user interface for a workspace of the collaborative system of FIG. 1;

FIG. 7 is another example user interface for a workspace of the collaborative system of FIG. 1;

FIG. 8 is a flowchart of an example method for recommending one or more workflow requests for a product design within the collaborative system of FIG. 1;

FIG. 9A is another example user interface for a workspace of the collaborative system of FIG. 1;

FIG. 9B is another example user interface for a workspace of the collaborative system of FIG. 1; and

FIG. 9C is another example user interface for a workspace of the collaborative system of FIG. 1.

The drawings, described below, are provided for purposes of illustration, and not of limitation, of the aspects and features of various examples of embodiments described herein. For simplicity and clarity of illustration, elements shown in the drawings have not necessarily been drawn to scale. The dimensions of some of the elements may be exaggerated relative to other elements for clarity. It will be appreciated that for simplicity and clarity of illustration, where considered appropriate, reference numerals may be repeated among the drawings to indicate corresponding or analogous elements or steps.

### DESCRIPTION OF EXAMPLE EMBODIMENTS

A collaborative system can enable collaboration between multiple users during a product design process. A collaborative design project typically involves various design documents for a product being developed. For complex products, multiple levels of design documents and multiple design documents for various components may be involved. Multiple users may collaborate to solve various design issues during a product design process.

Historical user feedback and/or messages between users during the collaborative product design process may include information that can be useful during a current design process. It can be challenging to locate the relevant information in the historical user feedback. The user feedback can include different formats of unstructured data (e.g., user input comments, item status, outcome descriptions, ticket status etc.). The user feedback can be related to different products and in some cases the user feedback for a different product may not be useful to the current design process/product. It can be challenging to identify cases in which the user feedback for a different product may be relevant and useful to a current design process/product.

The various embodiments described herein generally relate to systems and methods for providing a recommendation for a product design within a collaborative system. As will be described, the disclosed systems and methods can evaluate a received design document related to a product to identify design characteristics associated with the product and/or the design process. The disclosed systems and methods can identify related prior design feedback associated with the identified design characteristics. This can enable identification of related prior design feedback that corresponds to a different product.

The related prior design feedback and a related prior design decision can be evaluated to determine a relevance level of the related prior design decision for the current product design. This can enable identification of relevant prior design decisions when the user feedback includes different formats of unstructured data.

The disclosed systems and methods can evaluate the related prior design feedback and related prior design decision to determine design risks associated with the current product design and offer recommendations to address the determined design risks. The recommendations can be generated based on the relevance level of the related prior design decision. The recommendation may be offered by generating a natural language summary for the related prior design feedback and the related prior design decision. This can enable actionable recommendations to be provided to different types of users.

The disclosed systems and methods can provide predictive functionality where future risks to the design process are identified and recommendations are provided to address the future risks.

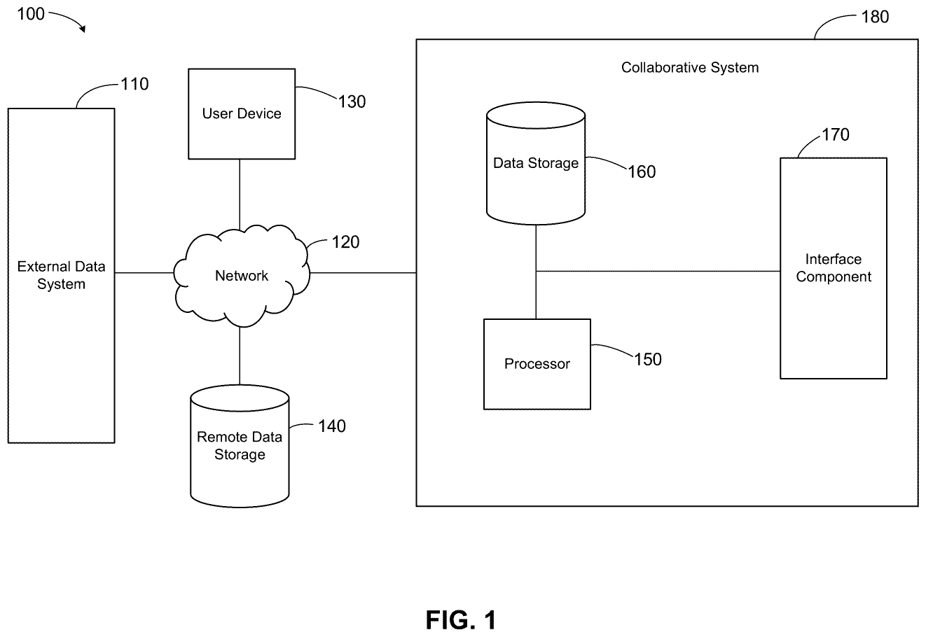

Reference is now made to FIG. 1, which illustrates a block diagram of components interacting with a collaborative system 180 in accordance with an example embodiment. As shown in FIG. 1, collaborative system 180 can be in communication with an external data system 110, a user device 130 and a remote data storage 140 via a network 120.

Collaborative system 180 includes a processor 150, a data storage 160, and an interface component 170. Processor 150, data storage 160, and interface component 170 may be implemented in software or hardware, or a combination of software and hardware. Processor 150, data storage 160, and interface component 170 can be combined into a fewer number of components or may be separated into further components. Collaborative system 180 may, in some embodiments, be split into multiple computing systems that may be distributed over a wide geographic area and connected via network 120.

Processor 150 is configured to control the operation of collaborative system 180. Processor 150 may be any suitable processors, controllers or digital signal processors that can provide sufficient processing power depending on the configuration, purposes and requirements of collaborative system 180. In some embodiments, processor 150 can include more than one processor with each processor being configured to perform different dedicated tasks. For example, processor 150 can provide a recommendation for a product design within collaborative system 180.

Data storage 160 can include RAM, ROM, one or more hard drives, one or more flash drives or some other suitable data storage elements such as disk drives, etc. For example, data storage 160 can also store product structures related to multiple different products, and related data, such as but not limited to design documents and metadata related to the products and the design documents. For example, and not of limitation, the design documents can include an Adobe Photoshop file (PDS), an Adobe Illustrator file (AI), an Adobe InDesign file (INDD), an Adobe PDF file (PDF), an Adobe XD file (XD), a CorelDraw file, (CDR), an AutoCAD file (DWG or DFX), a SketchUP file (SKP), a SolidWorks file (SLDPRT), an image file (JPG, JPEG, GIF, PNG), a scalable vector graphics file (SVG), a Revit file (RVT), a stereolithography file (STL), a computer-aided design file (CAD), or any combination of these documents.

Interface component 170 may be any interface that enables collaborative system 180 to communicate with other devices and systems. Interface component 170 may also include at least one of an Internet, Local Area Network (LAN), Ethernet, Firewire, modem or digital subscriber line connection. Various combinations of these elements may be incorporated within interface component 170. For example, interface component 170 may receive input from various input devices, such as a mouse, a keyboard, a touchscreen, a thumbwheel a track-pad, a track-ball, a card-reader, voice recognition software and the like depending on the requirements and implementation of collaborative system 180.

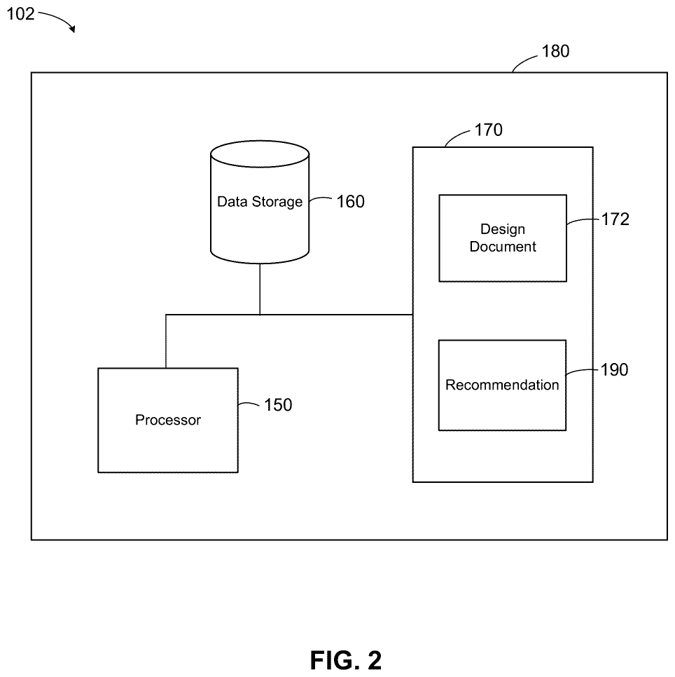

Further, interface component 170 can provide a user interface (UI) for a user to interact with collaborative system 180. The user interface provided by interface component 170 can enable the user to interact with collaborative system 180 in a number of ways, including but not limited to, interacting with design documents, submitting feedback related to the design documents and/or receiving recommendations for product design. For example, FIG. 2 shows a block diagram 102 of example components of collaborative system 180. Collaborative system 180, via interface component 170, can offer a user interface via which various documents, such as but not limited to design documents 172, and related product design recommendations 190 can be shown.

External data system 110, as described above, may share with and/or receive design data from collaborative system 180 via network 120. External data system 110 may include various different data and/or project management systems, such as but not limited to Product Data Management (PDM) systems and Product Lifecycle Management (PLM) systems. Although only one external data system 110 is shown for ease of exposition, it will be understood that more than one external data system 110 can communicate with collaborative system 180 at any one time. In some embodiments, external data system 110 can share design data with collaborative system 180 contemporaneously and/or successively with other external data systems 110.

Remote data storage 140 can include RAM, ROM, one or more hard drives, one or more flash drives or some other suitable data storage elements. Remote data storage 140 may also include one or more database(s) or file system(s). Although only one remote data storage 140 is shown for ease of exposition, there may be multiple remote data storage 140 distributed over a wide geographic area and connected via network 120. Remote data storage 140 can be used to store back-up data in some embodiments, and/or data less frequently accessed by collaborative system 180. For example, remote data storage 140 can store data related to completed projects and/or inactive users.

User device 130 may be any networked device operable to connect to network 120. A networked device is a device capable of communicating with other devices through a network such as network 120. A networked device may couple to network 120 through a wired or wireless connection. These external user devices 130 may include at least a processor and a data storage, and may be an electronic tablet device, a personal computer, workstation, server, portable computer, mobile device, personal digital assistant, laptop, smart phone, WAP phone, an interactive television, video display terminals, gaming consoles, and portable electronic devices or any combination of these. Although only one user device 130 is shown, it will be understood that more than one user device 130 can communicate with collaborative system 180 at any one time via network 120. User device 130 can be used by a user, whether a user internal to the organization using the collaborative system or a third-party user external to that organization, to access collaborative system 180. In some embodiments, a connection request initiated from user device 130 may be initiated from a web browser or application and directed at the browser-based or application-based interface offered by interface component 170 of collaborative system 180.

Network 120 may be any network capable of carrying data including the Internet, Ethernet, plain old telephone service (PTOS) line, public switch telephone network (PSTN), integrated services digital network (ISDN), digital subscriber line (DSL), coaxial cable, fiber optics, satellite, mobile, wireless (e.g., Wi-Fi, WiMAX), SS7 signaling network, fixed line, local area network, wide area network, and others, including any combination of these, capable of interfacing with, and enabling communication between collaborative system 180, user device 130, and remote data storage 140.

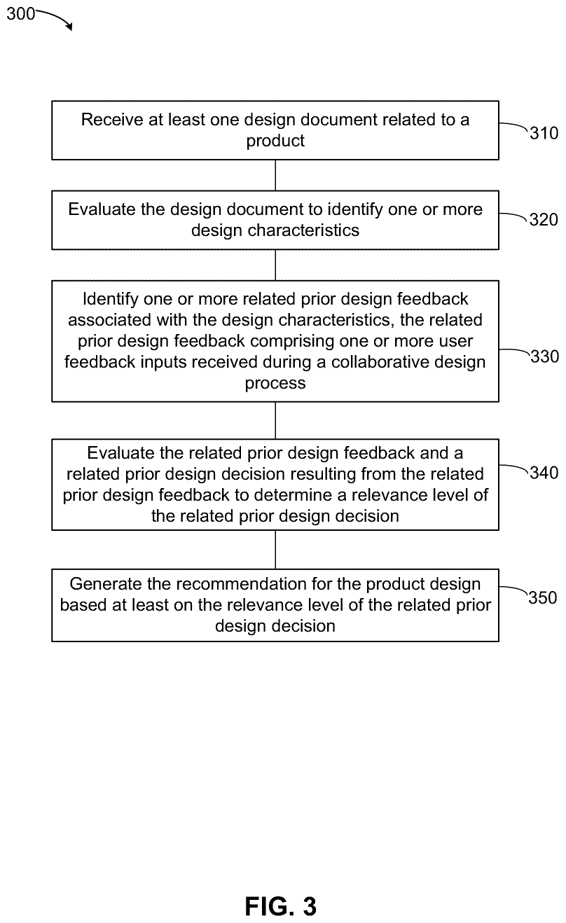

Reference is now made to FIG. 3, showing a flowchart of an example method 300 for providing a recommendation for a product design within the collaborative system 180.

The recommendation can be for a product design for a new product or an existing product. For a new product, there may not be any existing product designs and method 300 can provide a recommendation for a new product design for the new product. For an existing product, method 300 can provide a recommendation for a new product design for the existing product or a recommendation for modification to an existing product design for the existing product.

The collaborative system 180 can perform method 300 at various times. For example, the collaborative system 180 can perform method 300 at an initial development stage of a new product design, at intermediate or final development stages of a new product design, at a modification/improvement stage of an existing product design.

The collaborative system 180 can perform method 300 in response to a user input, for example, in response to an input from a user of the collaborative system 180. In some embodiments, the collaborative system 180 can automatically perform method 300, e.g., in response to a design document being imported or opened, and/or in response to launch of a collaboration session between users of the collaborative system 180.

At 310, the collaborative system 180 can receive at least one design document related to a product, such as but not limited to one or more design documents from external data system 110, user device 130, remote data storage 140, and data storage 160.

In some embodiments, the design document can be an engineering requirement, a bill of materials, a design drawing, a CAD model, or a combination of any of these. For example, the design document can be an engineering requirement describing the required design specifications for a new product. As another example, the design document can be a CAD model and a bill of materials of an existing product design that is being modified.

At 320, the collaborative system 180 can evaluate the at least one design document received at 310 to identify one or more design characteristics. For example, the processor 150 can evaluate the received design document to identify one or more design characteristics. The design characteristics can be associated with at least one of the product and a design process related to the product.

The design characteristic can be, for example, any aspect or feature associated with the product. For example, the product may be an electric vehicle powertrain that includes a front drive unit, a rear drive unit and a battery pack. The design characteristics may include type and size dimensions of the components (front drive unit, rear drive unit and battery pack) and/or aspects of the assembly process of the components (e.g., assembly sequence, interconnections between the components etc.). As another example, the product may be a digital camera that includes a camera body, multiple lenses, an image sensor, a memory device and an energy storage device. The design characteristics may include, but not limited to, type and size dimensions of the components, a number and relative positioning of the lenses, etc.

In some embodiments, the design characteristic can be associated with a design process related to the product. For example, the design characteristic may be associated with a stage of the design process and the design document may be evaluated to identify the stage (e.g., concept development, prototype design, testing and validation, final product design) of the design process.

In some embodiments, the collaborative system 180 can evaluate the at least one design document to identify one or more design characteristics by determining a geometry of a computer-generated model representing at least one portion of the product. For example, the received design document may include a CAD model of a part. Determining the geometry of the part may include summarizing one or more geometric features (e.g., length, width, height, thickness, area, volume, shape, etc.) of the part. The summarized geometric features may include position, orientation, size etc. of specific geometric features (e.g., holes, flanges etc.).

In some embodiments, the collaborative system 180 can evaluate the at least one design document to identify one or more design characteristics by parsing a document metadata of the at least one design document. The metadata may include, for example, a file type or format, a file name, a file size, a document number, a version number, associated users (e.g., creators, editors etc.), associated dates (e.g., creation date, last modified date etc.), keywords or tags, a document storage location, or any combination of these.

In some embodiments, the collaborative system 180 can evaluate the at least one design document to identify one or more design characteristics by identifying a product structure for the product. The product structure can define one or more hierarchical relationships between a product and one or more subcomponents of the product.

At a high level, a product structure identifies the parts that combine to make the overall product. The product structure can be depicted as a hierarchy of components. For example, at the top of the hierarchy is the product, and each lower hierarchical level of the product structure includes the subcomponents of the product.

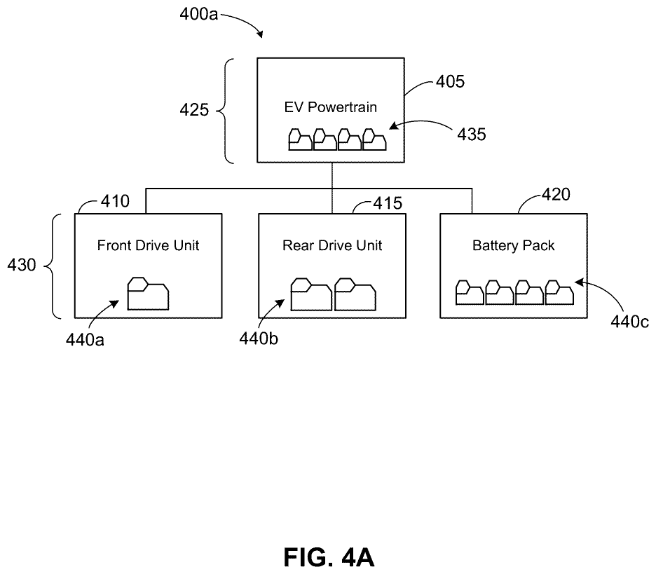

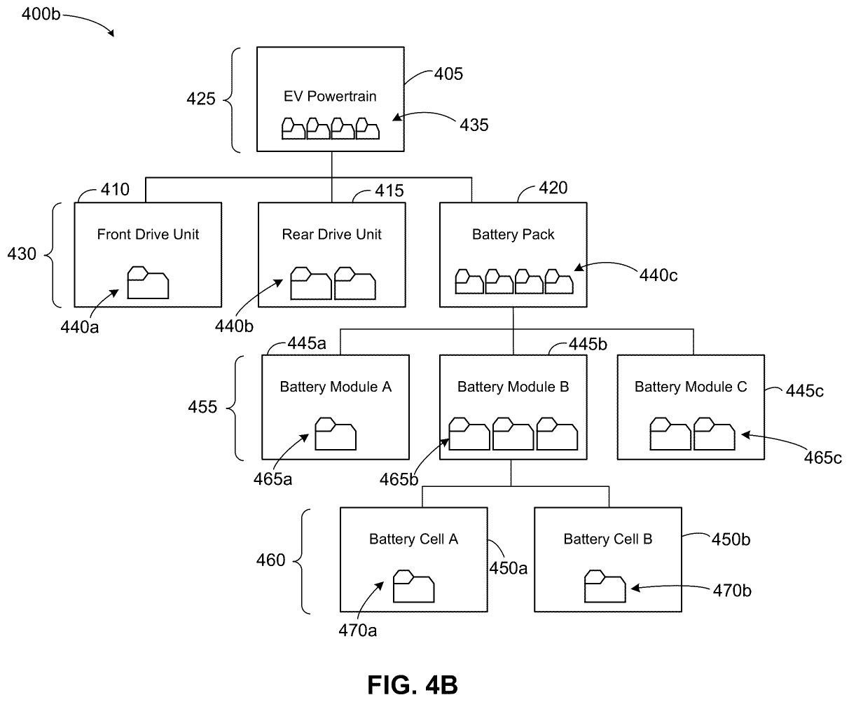

Reference is now made to FIG. 4A, showing a graphical representation of an example product structure 400a for an electric vehicle powertrain 405. Product structure 400a includes subcomponents 410, 415 and 420 in a hierarchical relationship with product 405 with hierarchical levels 425 and 430. The graphical representation of product structure 400a shown in FIG. 4A is for illustrative purposes and other manners of storing the relationship between product 405 and subcomponents 410, 415 and 420 can be applied.

Each product 405 and subcomponents 410, 415 and 420 can be represented as a node within product structure 400a. Product 405 is represented as a node at first hierarchical level 425 and the subcomponents (front drive unit 410, rear drive unit 415 and battery pack 420) are represented as nodes at second hierarchical level 430.

Each node 405, 410, 415, 420 within product structure 400a can be associated with corresponding design data. For example, as shown in FIG. 4A, node 405 is associated with design data 435, node 410 is associated with design data 440a, node 415 is associated with design data 440b, and node 420 is associated with design data 440c. The design data associated with each node can vary depending on various factors related to the product and/or the design process. The design data can include one or more design documents including, for example, an engineering requirement, a bill of materials, a design drawing, a CAD model, or any combination of these.

Reference is now made to FIG. 4B showing a graphical representation of another example product structure 400b for powertrain 405. Similar to product structure 400a (shown in FIG. 4A), product structure 400b includes subcomponents 410, 415, and 420 in a hierarchical relationship with product 405 in hierarchical levels 425 and 430. Product structure 400b further includes the product structure of battery pack 420, which includes a first hierarchical level 455 and a second hierarchical level 460. When referenced within the context of product structure 400b, first hierarchical level 455 may be referred to as third hierarchical level 455 and second hierarchical level 460 may be referred to as fourth hierarchical level 460. Although not shown in FIG. 4B, similar to battery pack 420, front drive unit 410 and/or rear drive unit 415 can be associated with subcomponents and corresponding product structures.

Battery pack 420 node is associated with a battery module A 445a, a battery module B 445b, and a battery module C 445c at third hierarchical level 455. Further, battery module B 445b is associated with a battery cell A 450a and a battery cell B 450b at fourth hierarchical level 460. Although not shown in FIG. 4B, similar to battery module B 445b, battery module A 445a and/or battery module C 445c can be associated with subcomponents and corresponding product structures. In the illustrated example, nodes 445a, 445b, 445c, 450a, and 450b are associated with design data 465a, 465b, 465c, 470a and 470b, respectively.

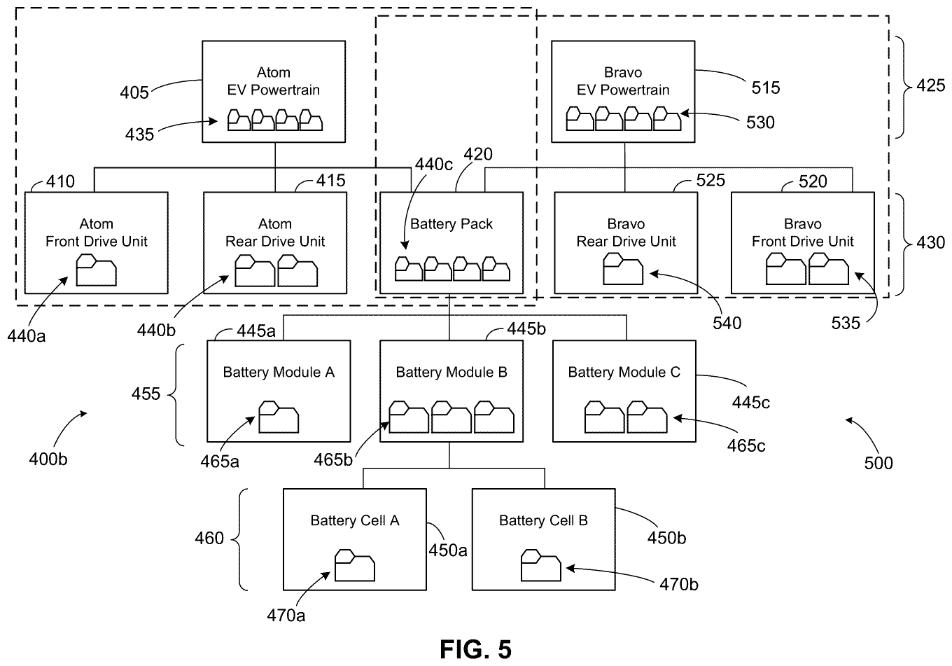

Reference is now made to FIG. 5 showing a graphical representation of example product structures 400b and 500 for powertrains 405 and 515 respectively. In FIG. 5, EV Powertrain 405 (of FIG. 4B) is identified as Atom EV Powertrain 405. Product structure 500 of powertrain 515 is similar to that of product structure 400b in that product structure 500 includes subcomponents 520, 525 and 420 in a hierarchical relationship with powertrain 515 with hierarchical levels 425 and 430. In the illustrated example, powertrains 405 and 515 share the same battery pack 420 and so, the product structure associated with battery pack 420 is common between powertrains 405 and 515.

In some cases, organizations may have multiple product lines with products that may share subcomponents. In the illustrated example, an electric automotive company may have an “Atom” EV product line and a “Bravo” EV product line within their EV fleet. Both Atom and Bravo can use the same EV battery pack design (e.g., 420). Instead of having to duplicate all the design data associated with battery pack 420, each of product structures 400b and 500 can reference the product structure associated with battery pack 420. In this way, when designers are working on the design of battery pack 420, any feedbacks and edits made to that design will be available for each of the “Atom” and “Bravo” design teams.

Referring back now to FIG. 3, at 310, a product structure node associated with a received design document can be first identified. The product structure can be used to identify additional nodes that are related to the first node. One or more design characteristics can be identified based on the design data of the first node or the additional related nodes.

For example, with reference to product structures 400b and 500 shown in FIG. 5, the received design document may be a bill of materials for Battery Module B and node 445b associated with the received design document may be first identified. Further, additional nodes related to node 445b may be identified. The additional nodes identified may be nodes at higher hierarchical levels and/or lower hierarchical levels in relation to the first node. If both higher and lower hierarchical levels nodes are identified, the additional nodes identified in this example can be nodes 405, 515, 420, 450a and 450b. Further, design characteristics can be identified based on the design data 465b, 435, 530, 440c, 470a and/or 470b of nodes 445b, 405, 515, 420, 450a and/or 450b respectively.

In some embodiments, the collaborative system 180 can evaluate the design document received (at 310) to identify one or more design characteristics by identifying a workspace associated with the product design and analyzing the workspace metadata associated with the identified workspace. The collaborative system 180 can then determine one or more design trends from the workspace metadata.

For example, the received design document may be a CAD model that was developed using a collaborative workspace provided by collaborative system 180. The CAD model may be developed in the collaborative workspace by collaboration between multiple users. At 320, the collaborative workspace associated with the CAD model may be identified (e.g., using metadata of the design document).

Further, workspace metadata associated with the collaborative workspace may be analyzed. The workspace metadata may include for example, number of users, type of users, collaboration level (e.g., number of collaborative messages, frequency of collaborative messages etc.), and/or collaboration duration (e.g., time duration between a first and final draft of the CAD model, time durations of the concept, prototype, development and product finalization stages etc.).

Further, one or more design trends may be determined from the workspace metadata. For example, a high number of users and/or a high frequency of collaboration messages may indicate a higher probability of changes to the current design. As another example, a total time duration of a prototype development stage compared with an average time duration of prototype development may indicate that the prototype stage is close to completion.

At 330, the collaborative system 180 can identify one or more related prior design feedback associated with the design characteristics identified at 320. The related prior design feedback can be identified from a historical design data storage that is configured to store historical or prior design feedback. For example, the processor 150 can identify related prior design feedback associated with the design characteristics from a historical design data storage stored in data storage 160.

The prior design feedback can include one or more user feedback inputs received during a collaborative design process between users in respect of a different product design. In some examples, the different product design may be related to the same product as the received design document. For example, the received design document may be related to a battery module of an EV powertrain and the prior design feedback may have been received during a collaborative design process of the front drive unit of the same EV powertrain. As another example, the received design document may be related to a finalized product design of a rear drive unit and the prior design feedback may have been received during a collaborative design process of the prototype of the same rear drive unit.

In some examples, the different product design may be related to a different product. For example, the received design document may be related to an EV powertrain and the prior design feedback may have been received during a collaborative design process of a digital camera.

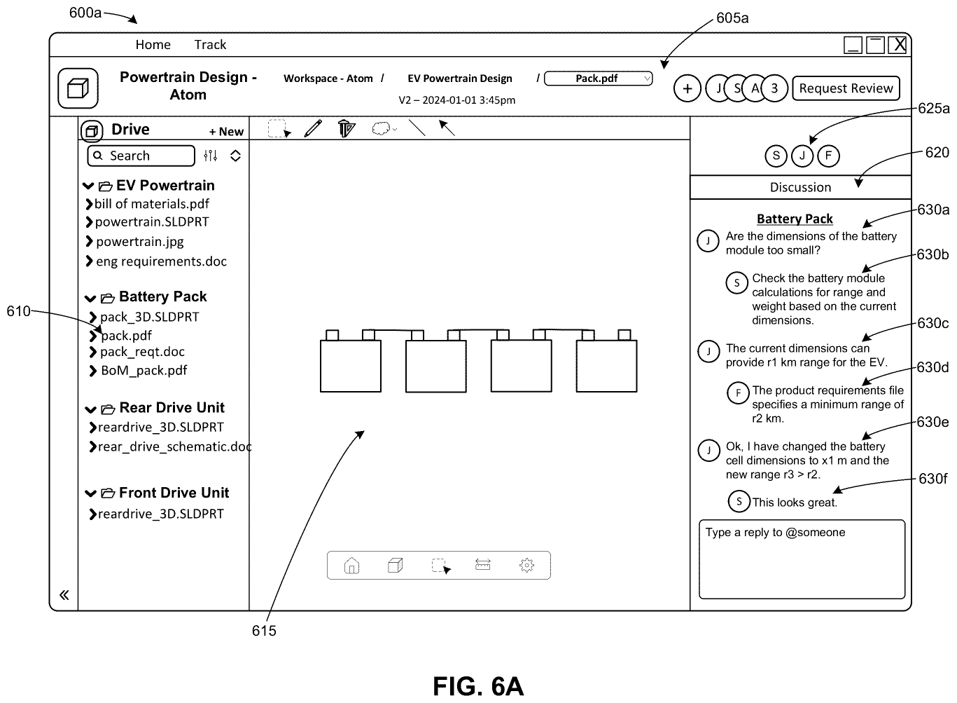

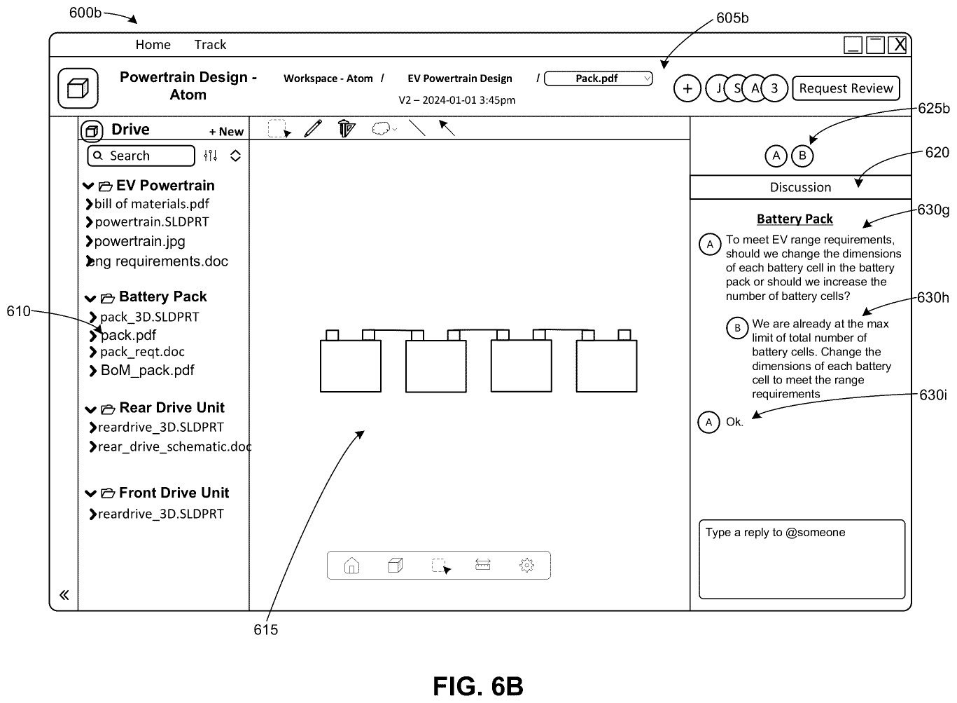

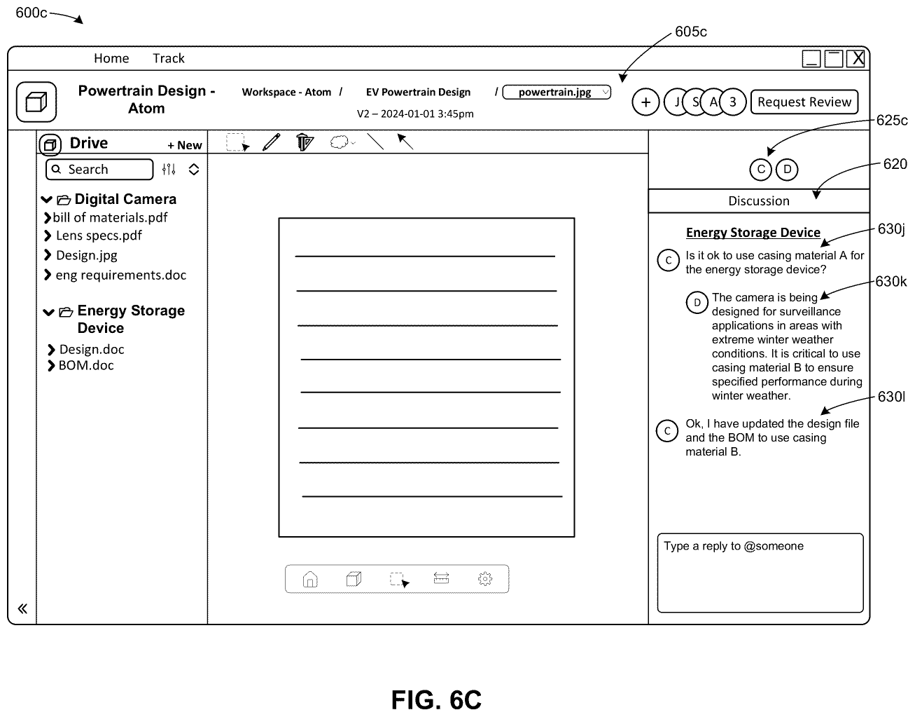

The user feedback inputs can include messages between users of a collaboration workspace that was used for the prior design. For example, the user feedback inputs can include messages between users of collaboration system 180. Reference is now made to FIG. 6A showing an example user interface 600a for a workspace 605a of collaborative system 180. Workspace 605a is an electronic environment offered by collaborative system 180 via which users can review design documents and share user feedback inputs related to the design documents.

The received design document can be a PDF document 610 that includes a block diagram 615 of a battery pack. User interface 600a can display block diagram 615 in a portion of workspace 605a. Workspace 605a may include a portion 620 to enable collaboration between users 625a. Portion 620 may display messages (e.g., messages 630a-630f, also collectively referred to herein as messages 630) between users 625a. Messages 630 may be received by collaboration system 180 during a collaborative design process between users 625a for development of a product design for a battery pack of an EV powertrain.

In some embodiments, the collaborative system 180 can identify the related prior design feedback by applying a product design data model to the design characteristics (identified at 320) to identify a plurality of related prior design feedback. The product design data model can be any suitable AI or machine learning model that is trained to correlate prior design feedback with design characteristics. For example, the product design data model can be a large language model (LLM). The LLM can be trained on specific languages based on types of design documents that may be received. For example, the LLM may be trained on specific language related to 3D XML CAD formats. In some embodiments, the LLM can be a language representation model (LRM).

The product design model can provide a confidence level for each related prior design feedback that is identified. A higher confidence level can indicate a higher correlation (compared with a lower confidence level) of the identified prior design feedback with the design characteristics.

For example, the collaborative system 180 can identify a related prior design feedback based on the geometrical features of the associated products (i.e., the product associated with the prior design feedback and the product associated with the received design document). Higher confidence levels may be generated for a higher similarity in size and/or shape. For an example design document related to an electric vehicle design, prior design feedback related to other models of electric vehicles may have a higher confidence level compared with prior design feedback related to lawnmowers. In some embodiments, the collaborative system 180 can identify a related prior design feedback based on pattern matching of the geometrical features (e.g., a pattern of holes for fasteners) and higher pattern similarity can result in higher confidence levels.

As another example, if a received design document corresponds to a final product design, related prior design feedback associated with final product designs may have higher confidence levels compared with the prior design feedback related to an initial prototype design.

As another example, related prior design feedback associated with similar product functionality may have a higher confidence level compared with a prior design feedback associated with a largely different product functionality. For a received design document related to a battery pack design for electrical energy storage in an electric vehicle, prior design feedback for a battery pack of a different product (e.g., a lawnmower) may result in a higher confidence level compared with prior design feedback related to a product that is unrelated to electrical energy storage.

As another example, related prior design feedback associated with a related product structure node may have a higher confidence level compared with prior design feedback associated with an unrelated node.

The training data can include a plurality of prior design feedback received during a plurality of prior product designs for a plurality of products. For example, the training data can include design characteristics associated with an EV powertrain and messages 630a-630f (shown in FIG. 6A) received by collaboration system 180 during a prior product design for a battery pack of the EV powertrain.

Reference is now made to FIG. 6B showing an example user interface 600b for a workspace 605b of collaborative system 180. In the illustrated example, workspace 605b includes messages 630g-630i received by collaboration system 180 during a collaborative design process between users 625b for development of another prior product design for a battery pack of an EV powertrain. The training data can include design characteristics associated with the EV powertrain and messages 630g-630i received by collaboration system 180 during a prior product design for the battery pack of the EV powertrain.

Reference is now made to FIG. 6C showing an example user interface 600c for a workspace 605c of collaborative system 180. In the illustrated example, workspace 605c includes messages 630j-630I received by collaboration system 180 during a collaborative design process between users 625c for product design of an energy storage device for a digital camera. The training data can include design characteristics associated with the digital camera and messages 630j-630I received by collaboration system 180 during a prior product design for the energy storage device of the digital camera.

At 330, the product design data model may identify a plurality of related prior design feedback based on the input design characteristics provided to the product design data model. In some embodiments, one or more related prior design feedback is selected from the plurality of related prior design feedback that are identified. Any suitable method can be used for the selection.

For example, the selection can be based on confidence levels (provided by the product design data model) of each of the plurality of related prior design feedback. A threshold confidence level may be used to select one or more related prior design feedback from the plurality of related prior design feedback. In some embodiments, a predetermined portion (e.g., 5% to 20%) of the plurality of related prior design feedback with highest confidence levels may be selected.

As another example, the selection can be based on a priority level assigned to the related prior design feedback. In some cases, the priority level may be assigned by a user of collaboration system 180. For example, a user may determine that a key design decision was taken during a collaborative design process and may assign a high priority level to the associated design feedback. In some cases, the priority level may be assigned automatically. For example, collaboration system 180 may automatically assign a high priority level to prior design feedback associated with specific users of collaboration system 180. As another example, collaboration system 180 may automatically assign a high priority level to prior design feedback associated with successful products.

As another example, the selection can be based on a feedback time period associated with a feedback conversation included in the related prior design feedback. The feedback time period may be defined as the time period between the first and last messages of a collaborative feedback conversation included in the related prior design feedback. A longer feedback time period may indicate that a larger amount of design considerations have been captured in the related prior design feedback. In some embodiments, related prior design feedback are selected that include a feedback conversation that takes longer than a predetermined priority feedback time period.

At 340, the collaborative system 180 can evaluate the one or more related prior design feedback (that was identified at 330) and a related prior design decision resulting from the related prior design feedback to determine a relevance level of the related prior design decision for the current product design. For example, processor 150 can evaluate the related prior design feedback and the related prior design decision to determine a relevance level of the related prior design decision.

In some embodiments, the collaborative system 180 can evaluate the related prior design feedback and the related prior design decision (resulting from the related prior design feedback) to determine one or more design risks associated with the current product design. The evaluation can be based on natural language processing of the related prior design feedback and/or related prior design decision.

For example, the related prior design feedback may include messages 630a-630f (shown in FIG. 6A) and the related prior design decision may be a change in the battery cell dimensions. The related prior design feedback and the related prior design decision may be evaluated to determine a design risk of insufficient range provided by battery module of current product design.

As another example, the related prior design feedback may indicate a large amount of time associated with developing a new prototype of a switched reluctance motor and the related prior design decision may be a delay in launch of the product. The related prior design feedback and the related prior design decision may be evaluated to determine a design risk of delayed product launch for the current product design.

The relevance level of the related prior design decision for the current product design may indicate an impact of the related prior design decision in addressing the determined design risks to the current product design. For example, a high relevance level may indicate that a recommendation based on the related prior design decision can successfully address the determined design risks to the current product design.

At 350, the collaborative system 180 can generate the recommendation for the product design based at least on the relevance level (determined at 340) of the related prior design decision. For example, processor 150 can generate the recommendation for the product design based on the relevance level of the related prior design decision.

A recommendation can include relevant information for consideration by a user. The relevant information can be information contained in user feedback inputs included in the related prior design feedback. For example, the recommendation may be generated using natural language processing of the user feedback inputs included in the related prior design feedback. In some embodiments, the recommendation can include identification of a potential problem for the product design and providing information related to the potential problem to the user.

In some embodiments, the collaborative system 180 can generate a natural language summary for the one or more related prior design feedback and the related prior design decision. The natural language summary can be generated, for example, using a large language model (LLM).

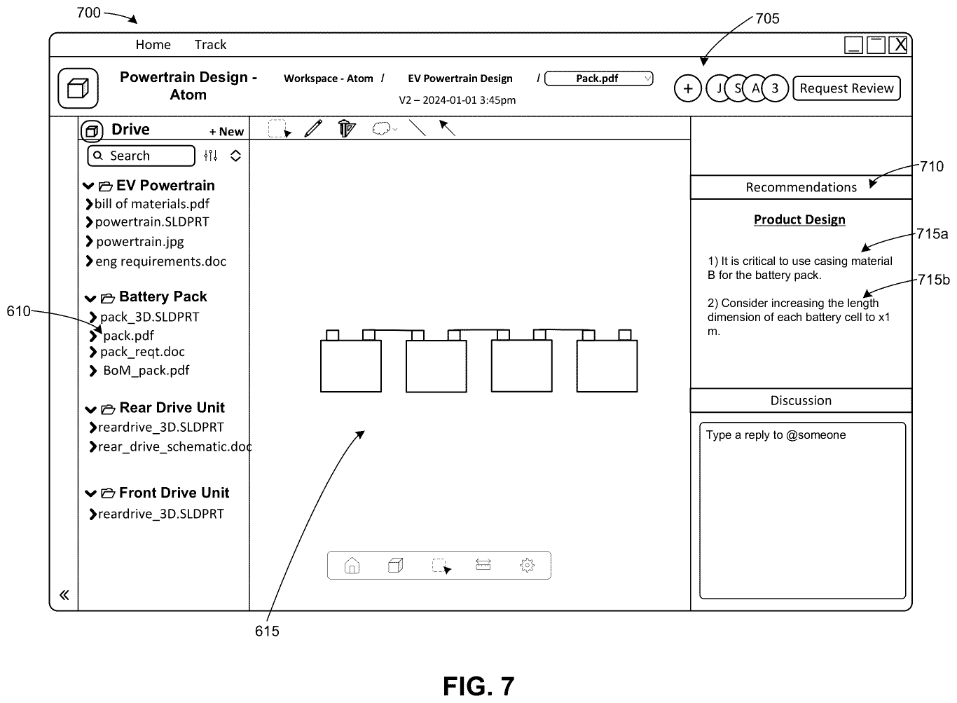

Reference is now made to FIG. 7 showing an example user interface 700 for a workspace 705 of collaborative system 180. Workspace 705 can offer recommendations to users of collaborative system 180 to address the determined design risks based on the related prior design decision.

Workspace 705 can include a display portion 710 that includes generated recommendations 715a and 715b. Recommendation 715a may be based on related prior design feedback and related prior design decision corresponding to messages 630j-630l shown in FIG. 6C. Recommendation 715a may be offered to address a design risk of incompatible casing material for the battery module of current product design. Recommendation 715b may be based on related prior design feedback and related prior design decision corresponding to messages 630a-630f shown in FIG. 6A. Recommendation 715b may be offered to address a design risk of insufficient range provided by battery module of current product design. Workspace 705 may determine that a relevance level of the prior design decision corresponding to messages 630g-630i shown in FIG. 6C is low (e.g., lower than a threshold relevance level) and not offer any recommendations based on this prior design decision.

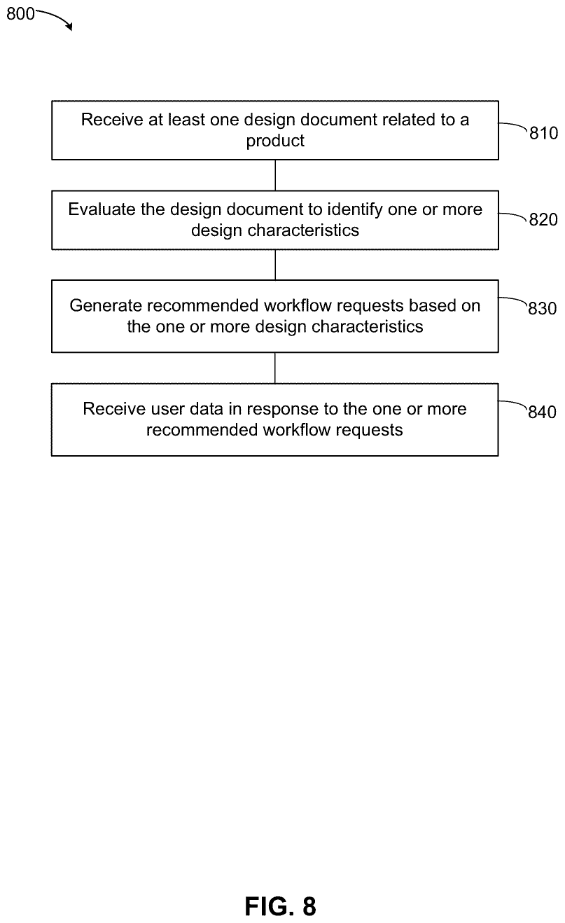

Reference is now made to FIG. 8, showing a flowchart of an example method 800 for recommending one or more workflow requests for a product design within the collaborative system 180. The workflow requests may enable a user to provide additional information related to the product design. The product design may be for a new or an existing product.

The collaborative system 180 can perform method 800 at various times. For example, the collaborative system 180 can perform method 800 at an initial development stage of a new product design, at intermediate or final development stages of a new product design, at a modification/improvement stage of an existing product design.

The collaborative system 180 can perform method 800 in response to a user input, for example, in response to an input from a user of the collaborative system 180. In some embodiments, the collaborative system 180 can automatically perform method 800, e.g., in response to a design document being imported or opened, and/or in response to launch of a collaboration session between users of the collaborative system 180.

At 810, the collaborative system 180 can receive at least one design document related to a product, such as but not limited to one or more design documents from external data system 110, user device 130, remote data storage 140, and data storage 160.

In some embodiments, the design document can be an engineering requirement, a bill of materials, a design drawing, a CAD model, or a combination of any of these. For example, the design document can be an engineering requirement describing the required design specifications for a new product. As another example, the design document can be a CAD model and a bill of materials of an existing product design that is being modified.

At 820, the collaborative system 180 can evaluate the at least one design document received at 310 to identify one or more design characteristics. For example, the processor 150 can evaluate the received design document to identify one or more design characteristics. The design characteristics can be associated with at least one of the product, a manufacturing process related to the product and a design process related to the product.

The design characteristic can be, for example, any aspect or feature associated with the product. For example, the product may be an electric vehicle powertrain that includes a front drive unit, a rear drive unit and a battery pack. The design characteristics may include type and size dimensions of the components (front drive unit, rear drive unit and battery pack) and/or aspects of the assembly process of the components (e.g., assembly sequence, interconnections between the components etc.). As another example, the product may be a digital camera that includes a camera body, multiple lenses, an image sensor, a memory device and an energy storage device. The design characteristics may include, but not limited to, type and size dimensions of the components, a number and relative positioning of the lenses, etc.

In some embodiments, the design characteristic can be associated with a design process related to the product. For example, the design characteristic may be associated with a stage of the design process and the design document may be evaluated to identify the stage (e.g., concept development, prototype design, testing and validation, final product design) of the design process.

In some embodiments, the design characteristic can be associated with a manufacturing process related to the product. For example, the design characteristic may be associated with a manufacturing tolerance of a component of an electric vehicle powertrain.

In some embodiments, the collaborative system 180 can evaluate the at least one design document to identify one or more design characteristics by determining a geometry of a computer-generated model representing at least one portion of the product. For example, the received design document may include a CAD model of a part. Determining the geometry of the part may include summarizing one or more geometric features (e.g., length, width, height, thickness, area, volume, shape, etc.) of the part. The summarized geometric features may include position, orientation, size etc. of specific geometric features (e.g., holes, flanges etc.).

In some embodiments, the collaborative system 180 can evaluate the at least one design document to identify one or more design characteristics by parsing a document metadata of the at least one design document. The metadata may include, for example, a file type or format, a file name, a file size, a document number, a version number, associated users (e.g., creators, editors etc.), associated dates (e.g., creation date, last modified date etc.), keywords or tags, a document storage location, or any combination of these.

In some embodiments, the collaborative system 180 can evaluate the at least one design document to identify one or more design characteristics by identifying a product structure for the product. The product structure can define one or more hierarchical relationships between a product and one or more subcomponents of the product.

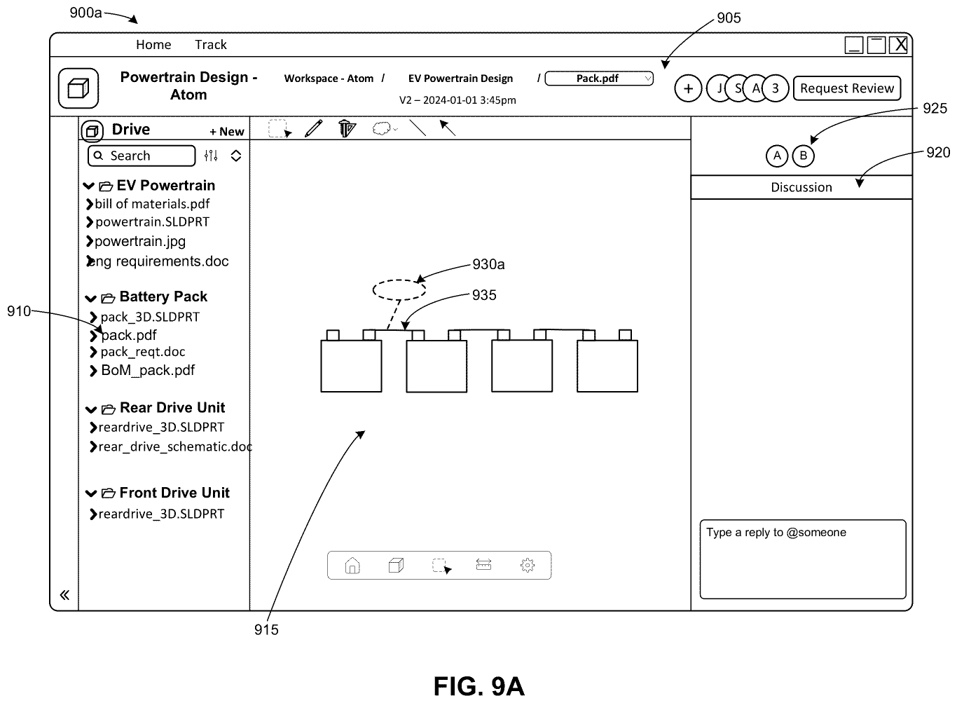

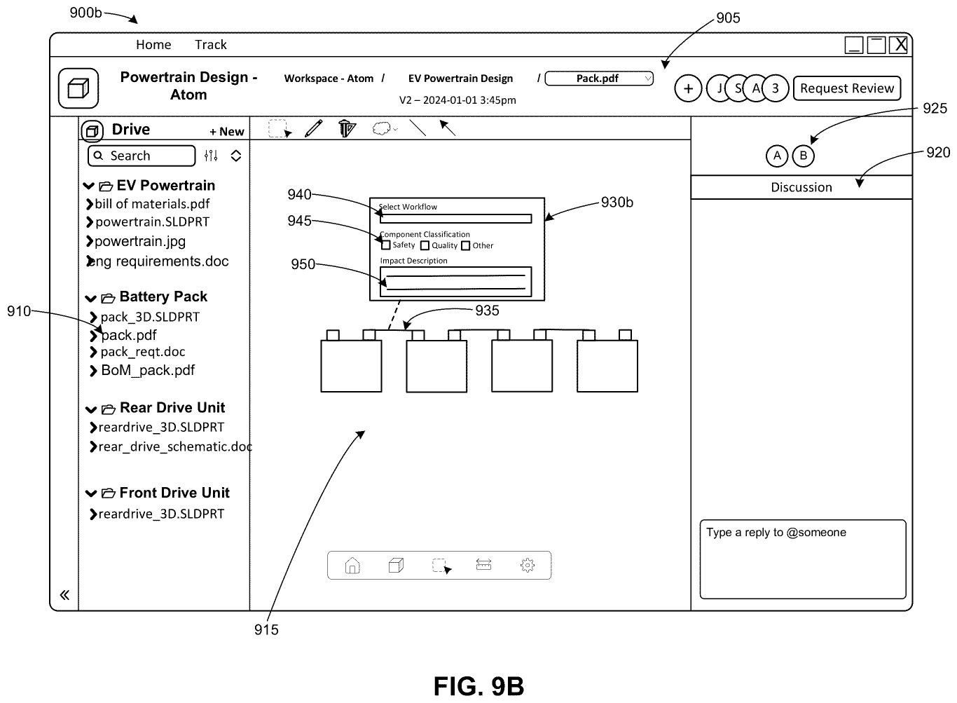

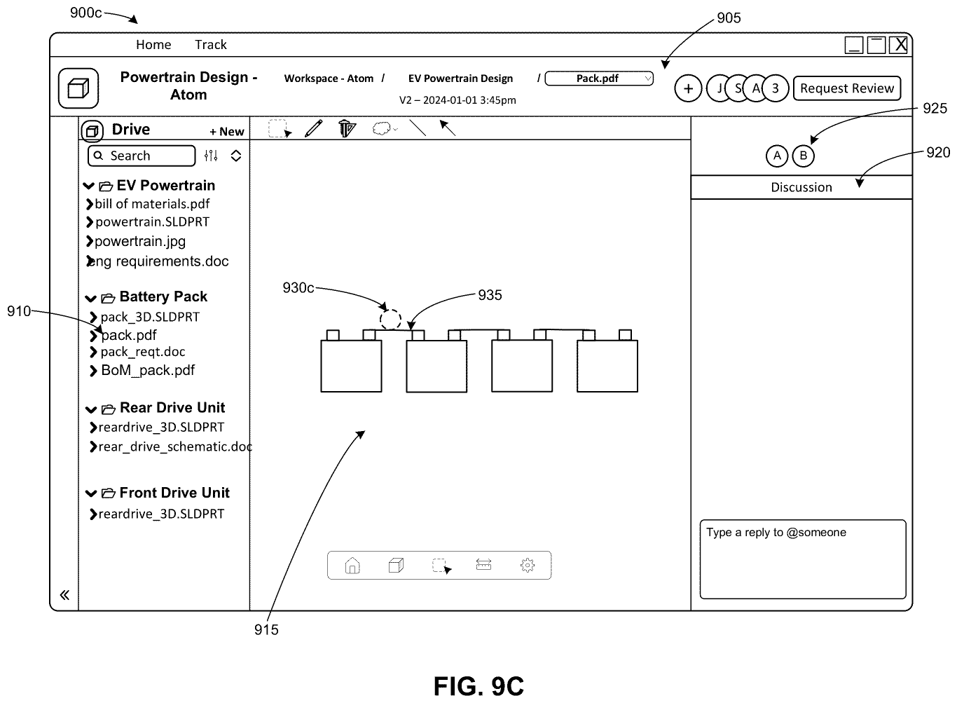

At 830, the collaborative system 180 can generate one or more recommended workflow requests based on the one or more design characteristics. Reference is now made to FIG. 9A showing an example user interface 900a for a workspace 905 of collaborative system 180. Workspace 905 is an electronic environment offered by collaborative system 180 via which users can review design documents, share user feedback inputs related to the design documents, and provide workflow data related to the design documents.

The received design document can be a PDF document 910 that includes a block diagram 915 of a battery pack. User interface 900a can display block diagram 915 in a portion of workspace 905. Workspace 905 may include a portion 920 to enable collaboration between users 925. Collaborative system 180 can generate one or more recommended workflow requests 930 that prompt users 925 to provide additional information related to the design document. For example, workflow request 930a may prompt users 925 to provide additional information associated with the battery pack and/or a component of the battery pack. In the illustrated example, workflow request 930a is provided as an on-screen annotation that is linked to a specific component (a connector 935 between adjacent battery cells of the battery pack). In other examples, collaborative system 180 may utilize any other suitable alternative to provide workflow requests 930. For example, workflow request 930 may be provided in a different portion of workspace 905a (e.g., as a system message in portion 920).

In some embodiments, collaborative system 180 may provide workflow request 930 as an interactive user interface element. For example, collaborative system 180 may provide an initial annotation indicating workflow request 930a and, in response to detecting a user interaction with the annotation, provide an expanded user interface element. The user interaction may be received, for example, via a touchscreen interface, a keyboard, a mouse, etc.

Reference is now made to FIG. 9B showing an example user interface 900b that includes an expanded user interface element generated for workflow request 930b. Workflow request 930b may include one or more recommended workflow requests that users 925 can select from. In the illustrated example, workflow request 930b includes a dropdown menu selection 940 that can provide recommended workflow requests that users 925 can select from. In other embodiments, workflow request 930b may include a different user interface element to provide the recommended workflow requests.

Each recommended workflow request may include multiple data fields to receive user data. In the illustrated example, workflow request 930b includes checkboxes 945 and textbox 950 to receive user data for the selected workflow request. In other examples, workflow request 930b may include any other combination of user interface elements to receive user data. For example, workflow request 930b may provide a different combination of user interface elements in response to users 925 selecting a different recommended workflow request.

In some embodiments, workflow request 930b may provide a configurable workflow request to users 925. For example, workflow request 930b may include two recommended workflow requests and one configurable workflow request for users 925 to select from. The configurable workflow request may enable users 925 to specify a type of workflow request, data field types and/or a number of data fields to be included in the workflow.

Collaborative system 180 can generate the recommended workflow requests and/or the configurable workflow requests based on the design characteristics identified at 820. For example, the identified design characteristics may indicate that the received design document is associated with a product having a finalized design and ready for manufacturing. In response, collaborative system 180 can generate a recommended workflow request in the form of a checklist including data fields corresponding to requesting supplier cost quotes for components of the product. As another example, the identified design characteristics may indicate that the received design document is associated with a product undergoing testing and validation. In response, collaborative system 180 can generate a recommended workflow request as a Failure Mode and Effects Analysis (FMEA) form that enables collaborative interaction between users 925 associated with product development and manufacturing teams. The FMEA form may include multiple data fields for users 925 to input data related to Design FMEA and Process FMEA. Users 925 may select one or more of the recommended workflow requests to provide workflow data.

In some embodiments, a user may utilize a configurable workflow request to customize the data input process and/or in response to unsuitable recommended workflow requests. A configurable workflow request 930b may enable users 925 to specify a type of workflow (e.g., a checklist, a form, a questionnaire, etc.), type(s) of data fields to be included in the workflow and/or labels for the included data fields.

In some embodiments, collaborative system 180 can generate one or more recommended workflow requests in response to receiving a user selection of one or more components within the received design document. For example, collaborative system 180 may initially display block diagram 915 of the battery pack without the annotation for workflow request 930a. Further, collaborative system 180 may generate the annotation for workflow request 930a in response to a user input (e.g., via a touchscreen user interface, a mouse, a keyboard, etc.) indicating selection of component 935. Collaborative system 180 may further display the annotation for workflow request 930a in association with the selected component (e.g., as illustrated in FIG. 9A). The generated workflow request may include one or more recommended workflow requests based on the design characteristics identified at 820 and the selected component. Optionally, the generated workflow request may include one or more user configurable workflow requests based on the design characteristics identified at 820 and the selected component.

At 840, collaborative system 180 can receive user data in response to the one or more recommended workflow requests. For example, a user may select a recommended workflow request in the form of a checklist for requesting supplier cost quotes and provide corresponding workflow data including, for example, supplier information, order quantity information and order policy information. As another example, a user may select a user configurable workflow request to input a FMEA form and specify form fields to be included for FMEA data related to one or more components.

In response to receiving the user data, collaborative system 180 can generate an annotation in the displayed user interface indicating the received user data. Reference is now made to FIG. 9C showing an example user interface 900c that includes an annotation generated to indicate user data received in response to a workflow request. A user may interact with the annotation to interact with the associated workflow data (for example, supplier cost quotes checklist data, FMEA form data, etc.). For example, a user may view and/or modify the workflow data.

In some embodiments, collaborative system 180 can store the received workflow data as an electronic object that is associated with the design document, the product and/or the component. For example, collaborative system 180 may store the received workflow data in association with component 935. Collaborative system 180 may use the stored association to generate an annotation indicating the user data in association with component 935 when displaying other design documents. Collaborative system 180 may store the received workflow data in any suitable location including, for example, data storage 160, external data system 110, and/or remote data storage 140.

In some embodiments, at 830, collaborative system 180 can identify one or more related prior design feedback associated with the design characteristics identified at 820. The related prior design feedback can be identified from a historical design data storage that is configured to store historical or prior design feedback. For example, collaborative system 180 can identify related prior design feedback associated with the design characteristics from a historical design data storage stored in data storage 160, external data system 110, and/or remote data storage 140. As described herein above, collaborative system 180 can identify the related prior design feedback by applying a product design data model to the identified design characteristics to enable identification of related prior design feedback.

The prior design feedback can include one or more workflow data received in response to recommended workflow requests for a different product design. In some examples, the different product design may be related to the same product as the received design document. For example, the received design document may be related to a battery module of an EV powertrain and the prior design feedback may have been received in response to recommended workflow requests for a front drive unit of the same EV powertrain. As another example, the received design document may be related to a finalized product design of a rear drive unit and the prior design feedback may have been received in response to recommended workflow requests for a prototype of the same rear drive unit.

In some examples, the different product design may be related to a different product. For example, the received design document may be related to an EV powertrain and the prior design feedback may have been received in response to recommended workflow requests for a digital camera.

Further, collaborative system 180 can determine relevance levels for the workflow data included in the related prior design feedback. The relevance level may be determined based on one or more factors including, for example, a stage of the product design process, a type of product, product structure, design document metadata, and/or workspace metadata. Further, collaborative system 180 can generate one or more recommended workflow requests based on the determined relevance levels and proceed to 840 to receive user data in response to the recommended workflow requests.

It will be appreciated that numerous specific details are set forth in order to provide a thorough understanding of the example embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description and the drawings are not to be considered as limiting the scope of the embodiments described herein in any way, but rather as merely describing the implementation of the various embodiments described herein.

The embodiments of the systems and methods described herein may be implemented in hardware or software, or a combination of both. These embodiments may be implemented in computer programs executing on programmable computers, each computer including at least one processor, a data storage system (including volatile memory or non-volatile memory or other data storage elements or a combination thereof), and at least one interface component. For example and without limitation, the programmable computers (user devices) may be a server, network appliance, embedded device, computer expansion module, a personal computer, laptop, personal data assistant, cellular telephone, smart-phone device, tablet computer, a wireless device or any other computing device capable of being configured to carry out the methods described herein.

In some embodiments, the interface component may be a network interface component. In embodiments in which elements are combined, the interface component may be a software interface component, such as those for inter-process communication (IPC). In still other embodiments, there may be a combination of interface components implemented as hardware, software, and combination thereof.

Program code may be applied to input data to perform the functions described herein and to generate output information. The output information is applied to one or more output devices, in known fashion.

Each program may be implemented in a high level procedural or object oriented programming and/or scripting language, or both, to communicate with a computer system. However, the programs may be implemented in assembly or machine language, if desired. In any case, the language may be a compiled or interpreted language. Each such computer program may be stored on a storage media or a device (e.g. ROM, magnetic disk, optical disc) readable by a general or special purpose programmable computer, for configuring and operating the computer when the storage media or device is read by the computer to perform the procedures described herein. Embodiments of the system may also be considered to be implemented as a non-transitory computer-readable storage medium, configured with a computer program, where the storage medium so configured causes a computer to operate in a specific and predefined manner to perform the functions described herein.

Furthermore, the system, processes and methods of the described embodiments are capable of being distributed in a computer program product comprising a computer readable medium that bears computer usable instructions for one or more processors. The medium may be provided in various forms, including one or more diskettes, compact disks, tapes, chips, wireline transmissions, satellite transmissions, internet transmission or downloadings, magnetic and electronic storage media, digital and analog signals, and the like. The computer useable instructions may also be in various forms, including compiled and non-compiled code.

Various embodiments have been described herein by way of example only. Various modification and variations may be made to these example embodiments without departing from the spirit and scope of the invention, which is limited only by the appended claims. Also, in the various user interfaces illustrated in the drawings, it will be understood that the illustrated user interface text and controls are provided as examples only and are not meant to be limiting. Other suitable user interface elements may be possible.

We claim:

1. A method for providing a recommendation for a product design within a collaborative system, the method comprising:
receiving at least one design document related to a product;
evaluating the at least one design document to identify one or more design characteristics associated with at least one of the product and a design process related to the product;
identifying one or more related prior design feedback associated with the one or more design characteristics from a historical design data storage, the one or more related prior design feedback comprising one or more user feedback inputs received during a collaborative design process between one or more users in respect of a different product design;
evaluating the one or more related prior design feedback and a related prior design decision resulting from the one or more related prior design feedback to determine a relevance level of the related prior design decision for the product design; and
generating the recommendation for the product design based at least on the relevance level of the related prior design decision.

2. The method of claim 1, wherein evaluating the at least one design document to identify one or more design characteristics comprises:
determining a geometry of a computer-generated model representing at least one portion of the product.

3. The method of claim 1, wherein evaluating the at least one design document to identify one or more design characteristics comprises:
parsing a document metadata of the at least one design document.

4. The method of claim 1, wherein evaluating the at least one design document to identify one or more design characteristics comprises:
identifying a product structure for the product, the product structure defining one or more hierarchical relationships between the product and one or more subcomponents of the product.

5. The method of claim 1, wherein evaluating the at least one design document to identify one or more design characteristics comprises:
identifying a workspace associated with the product design within the collaborative system;
analyzing a workspace metadata associated with the workspace; and
determining one or more design trends from the workspace metadata.

6. The method of claim 1, wherein identifying the one or more related prior design feedback associated with the one or more design characteristics from the historical design data storage comprises:
applying a product design data model to the one or more design characteristics to identify a plurality of related prior design feedback along with a confidence level for each related prior design feedback, the product design data model being trained on a plurality of prior design feedback received during a plurality of prior product designs for a plurality of products, and the product design data model being trained to correlate one or more prior design feedback with the one or more design characteristics; and
selecting the one or more related prior design feedback from the plurality of related prior design feedback.

7. The method of claim 6, wherein selecting the one or more related prior design feedback from the plurality of related prior design feedback comprises:
selecting the one or more related prior design feedback assigned a high priority level during the product design.

8. The method of claim 6, wherein selecting the one or more related prior design feedback from the plurality of related prior design feedback comprises:
identifying the one or more related prior design feedback from the plurality of related prior design feedback that is generated during a feedback conversation that takes longer than a priority feedback time period.

9. The method of claim 1, wherein generating the recommendation for the product design comprises:
evaluating the one or more related prior design feedback and the related prior design decision to determine one or more design risks associated with the product design; and
offering the recommendation for the product design to address at least one design risk of the one or more design risks based on the related prior design decision.

10. The method of claim 1, wherein generating the recommendation for the product design comprises:
generating a natural language summary for the one or more related prior design feedback and the related prior design decision.

11. A system for providing a recommendation for a product design within a collaborative system, the system comprising:
a design data storage operable to store one or more prior design feedback comprising one or more user feedback inputs received during a collaborative design process between one or more users in respect of a different product design; and
a processor configured to:
receive at least one design document related to a product;
evaluate the at least one design document to identify one or more design characteristics associated with at least one of the product and a design process related to the product;
identify, from the design data storage, one or more related prior design feedback associated with the one or more design characteristics;
evaluate the one or more related prior design feedback and a related prior design decision resulting from the one or more related prior design feedback to determine a relevance level of the related prior design decision for the product design; and
generate the recommendation for the product design based at least on the relevance level of the related prior design decision.

12. The system of claim 11, wherein the processor is configured to evaluate the at least one design document to identify one or more design characteristics by determining a geometry of a computer-generated model representing at least one portion of the product.

13. The system of claim 11, wherein the processor is configured to evaluate the at least one design document to identify one or more design characteristics by parsing a document metadata of the at least one design document.

14. The system of claim 11, wherein the processor is configured to evaluate the at least one design document to identify one or more design characteristics by identifying a product structure for the product, the product structure defining one or more hierarchical relationships between the product and one or more subcomponents of the product.

15. The system of claim 11, wherein the processor is configured to evaluate the at least one design document to identify one or more design characteristics by:
identifying a workspace associated with the product design within the collaborative system;
analyzing a workspace metadata associated with the workspace; and
determining one or more design trends from the workspace metadata.

16. The system of claim 11, wherein the processor is configured to identify the one or more related prior design feedback associated with the one or more design characteristics by:
applying a product design data model to the one or more design characteristics to identify a plurality of related prior design feedback along with a confidence level for each related prior design feedback, the product design data model being trained on a plurality of prior design feedback received during a plurality of prior product designs for a plurality of products, and the product design data model being trained to correlate one or more prior design feedback with the one or more design characteristics; and
select the one or more related prior design feedback from the plurality of related prior design feedback.

17. The system of claim 16, wherein the processor is configured to select the one or more related prior design feedback from the plurality of related prior design feedback by selecting the one or more related prior design feedback assigned a high priority level during the product design.

18. The system of claim 16, wherein the processor is configured to select the one or more related prior design feedback from the plurality of related prior design feedback by identifying the one or more related prior design feedback from the plurality of related prior design feedback that is generated during a feedback conversation that takes longer than a priority feedback time period.

19. The system of claim 11, wherein the processor is configured to generate the recommendation for the product design by:
evaluating the one or more related prior design feedback and the related prior design decision to determine one or more design risks associated with the product design; and
offering the recommendation for the product design to address at least one design risk of the one or more design risks based on the related prior design decision.

20. The system of claim 11, wherein the processor is configured to generate the recommendation for the product design by generating a natural language summary for the one or more related prior design feedback and the related prior design decision.

21. A method for recommending one or more workflow requests for a product design within a collaborative system, the method comprising:
receiving at least one design document related to a product;
evaluating the at least one design document to identify one or more design characteristics associated with at least one of the product, a manufacturing process, and a design process related to the product;
generating the one or more recommended workflow requests based on the one or more design characteristics; and
receiving user data in response to the one or more recommended workflow requests.

22. The method of claim 21, wherein generating the one or more recommended workflow requests based on the one or more design characteristics comprises:
determining from the one or more design characteristics one or more user configurable workflow requests.

23. The method of claim 21, wherein generating the one or more recommended workflow requests based on the one or more design characteristics comprises:
identifying one or more related prior design feedback associated with the one or more design characteristics from a historical design data storage, the one or more related prior design feedback comprising one or more workflow data received in respect of a different product design;
determining a relevance level for each workflow data of the one or more workflow data for the product design; and
selecting the one or more recommended workflow requests based on the relevance level of the one or more workflow data.

24. The method of claim 21 further comprising:
receiving a user selection of one or more components within the at least one design document; and
in response to receiving the user selection, generating the one or more recommended workflow requests based on the one or more design characteristics and the user selection.
